(19) United States
(12) Patent Application Publication
(10) Pub. No.: US 2012/0195094 A1
(43) Pub. Date: Aug. 2, 2012

(54) MEMORY SUPPORT PROVIDED WITH ELEMENTS OF FERROELECTRIC MATERIAL AND PROGRAMMING METHOD THEREOF

(75) Inventors: MAURIZIO GRECO, Acicastello (CT) (IT); Antonio Maria Scalia, Catania (IT)

(73) Assignee: STMicroelectronics S.r.I., Agrate Brianza (MI) (IT)

(21) Appl. No.: 13/362,434

(22) Filed: Jan. 31, 2012

(30) Foreign Application Priority Data
Feb. 1, 2011 (IT) TO2011A000079
Mar. 1, 2011 (IT) TO2011A000180

(51) Int. Cl. G11C 11/22

(52) U.S. Cl. 365/145

(57) ABSTRACT

Logic data is written in a memory having a first word line and a first bit line, with the memory including a first memory cell having a first ferroelectric transistor. The first ferroelectric transistor includes a layer of ferroelectric material and has a first conduction terminal coupled to the first bit line, and a control terminal coupled to the first word line. The logic data is written based on biasing the control terminal of the first ferroelectric transistor at a first biasing value, biasing the first conduction terminal of the first ferroelectric transistor at a second biasing value different from the first biasing value, and generating a stable variation of the state of polarization of the layer of ferroelectric material of the first ferroelectric transistor to write the logic data in the first memory cell.

### FIELD OF THE INVENTION

The present invention relates to a memory comprising elements made of ferroelectric material, and to a method for programming (or writing) the memory.

### BACKGROUND OF THE INVENTION

In the context of storage systems, there is a need for high storage capacities with high data-transfer rates (bitrates) while at the same time reducing manufacturing costs and size. Storage systems that are currently the most widely used, namely hard-disk drives (with miniaturized dimensions) and flash RAMS, present intrinsic technological limits in regards to increasing the data-storage capacity, the read/write speed, and the reduction of their dimensions.

Among the innovative approaches proposed, very promising are storage systems that use a storage medium made of ferroelectric material. Reading/writing of individual bits is performed by interacting with the ferroelectric domains of the ferroelectric material.

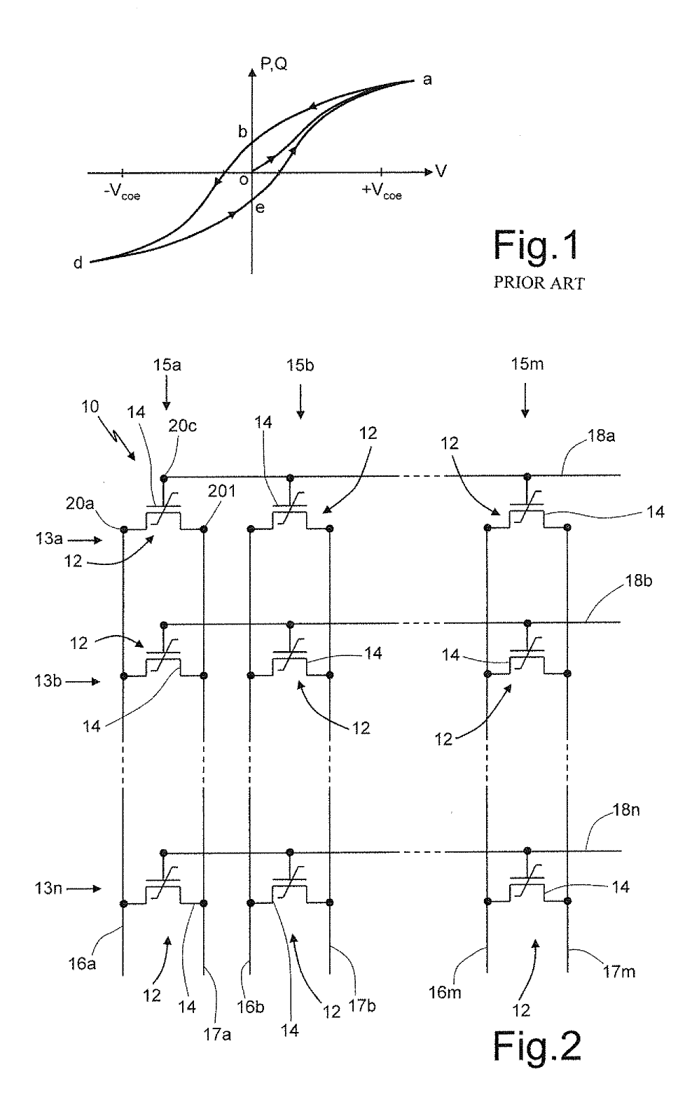

A ferroelectric material possesses a spontaneous polarization, which can be reversed by an applied electrical field, as shown in FIG. 1. The material, moreover, presents a hysteresis cycle (represented in the diagram of the polarization charge Q, or equivalently, of the polarization P) as a function of the applied voltage V. This exploits storage of logic values or bits. In particular, in the absence of a biasing voltage imparted on the medium (V=0), there exist two points of the diagram in the stable state (designated by “b” and “e”) that have different polarizations, which may be equal and opposite one another. The points can remain in the stable state for a long time, thus maintaining the binary data stored (e.g., point “b” with positive charge +Q_{H} corresponds to a “0”, while point “e” with negative charge −Q_{H}, corresponds to a “1”).

The writing operations may have application to the ferroelectric medium of a voltage, positive or negative, higher (in absolute value) than a coercive voltage V_{coe} characteristic of the ferroelectric material. In this case, stored in the material is a positive charge +Q_{H}, or a negative charge −Q_{H}. This basically corresponds to a displacement along the diagram from point “e” to point “b” passing through point “a”, or else from point “b” to point “e” passing through point “d”. A voltage having an absolute value that is lower than the coercive voltage V_{coe} does not, instead, cause a stable variation of the charge stored.

The data-reading techniques commonly used are based on a destructive operation, which may be based on erasure of the data read. In summary, a (positive or negative) voltage having an amplitude greater than that of the coercive voltage V_{coe} is applied to the ferroelectric material. This carries out a writing operation, and the occurrence or a reversal of polarity of the ferroelectric material is detected. For this purpose, the existence or otherwise an appreciable current that flows in the ferroelectric material is detected. Clearly, the application of a positive (or negative) voltage causes a reversal of the ferroelectric domains in which a negative charge −Q_{H} (or positive charge +Q_{H}) has previously been stored.

Documents that describe memories comprising ferroelectric elements and corresponding read/write methods include U.S. Pat. Nos. 5,086,412; 6,819,583 and 4,888,733. Each of the memory cells according to theses documents comprise one or more transistors for direct addressing of the memory cell, and at least one additional ferroelectric capacitor for storage of the charge that represents the logic information (bit “1” or bit “0”) to be stored.

### SUMMARY OF THE INVENTION

The approaches are, however, expensive in terms of area of occupation and are not optimal in terms of operation. For example, some of these memories present coupling problems between adjacent cells during the writing operations.

An object of the present invention is to provide a memory comprising elements made of ferroelectric material, and a method for programming the memory that will enable the abovementioned problems and disadvantages to be overcome.

According to the present invention, a memory comprising elements made of ferroelectric material and a method for programming the memory are provided, as defined in the annexed claims.

### DETAILED DESCRIPTION OF THE DRAWINGS

For a better understanding of the present invention, preferred embodiments thereof are now described, purely by way of non-limiting examples and with reference to the attached drawings, wherein:

FIG. 1 is a plot representing a hysteresis cycle of a ferroelectric material of a storage medium according to the prior art;

FIG. 2 shows a portion of a memory in which each memory cell is formed by a single FeFET according to the present invention;

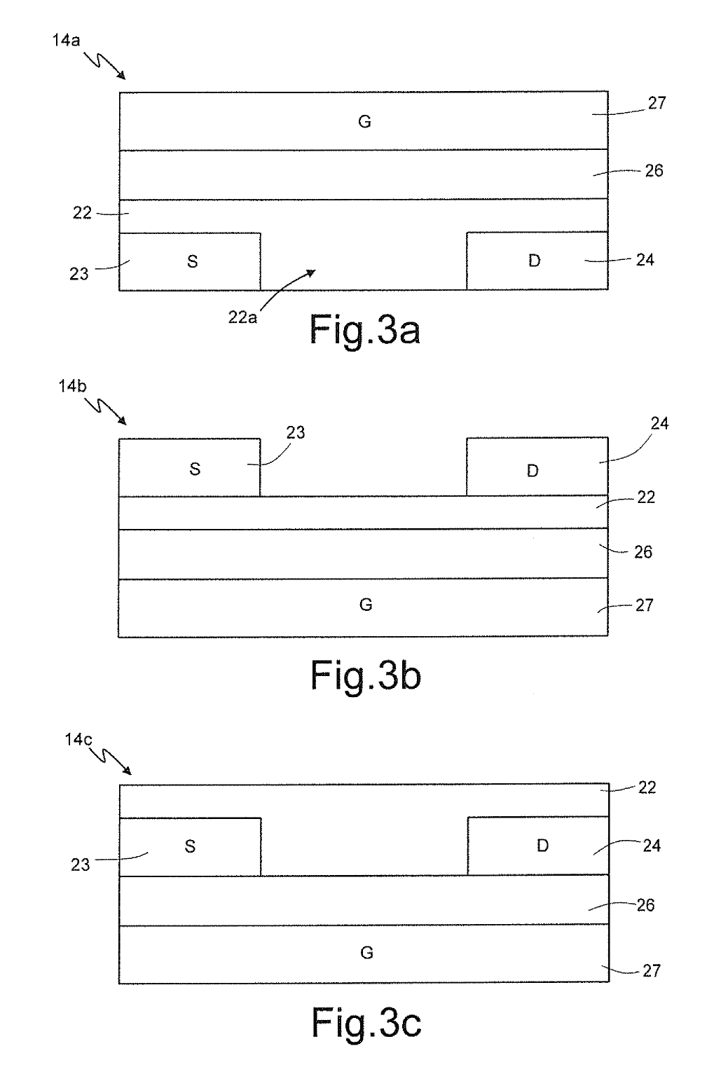

FIGS. 3a-3c show different embodiments of FeFETs that can be used in the memory portion of FIG. 2;

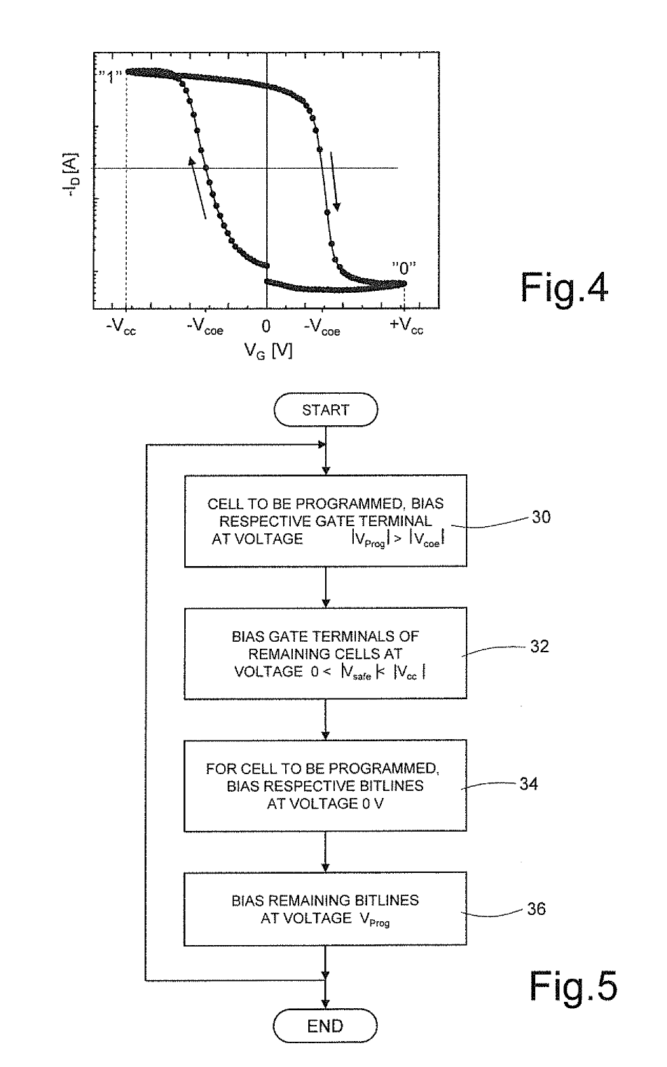

FIG. 4 shows an example of a transcharacteristic curve for a generic FeFET according to the present invention;

FIG. 5 shows steps of a method for programming (writing) memory cells of the memory portion of FIG. 2;

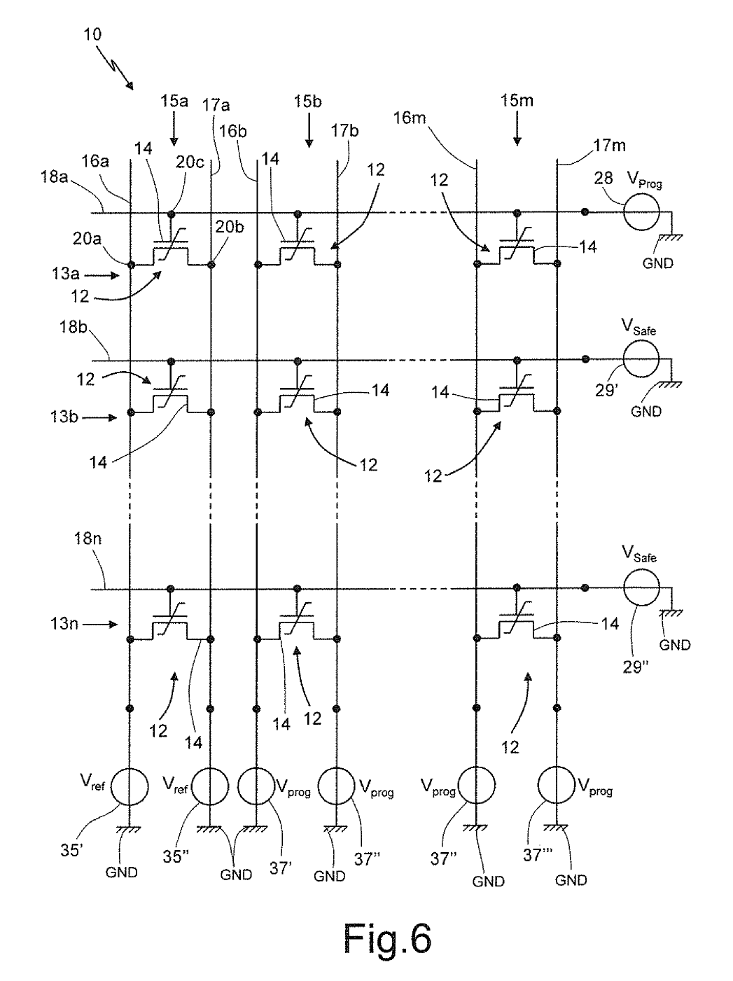

FIG. 6 shows the memory portion of FIG. 2 during a programming step according to the method of FIG. 5;

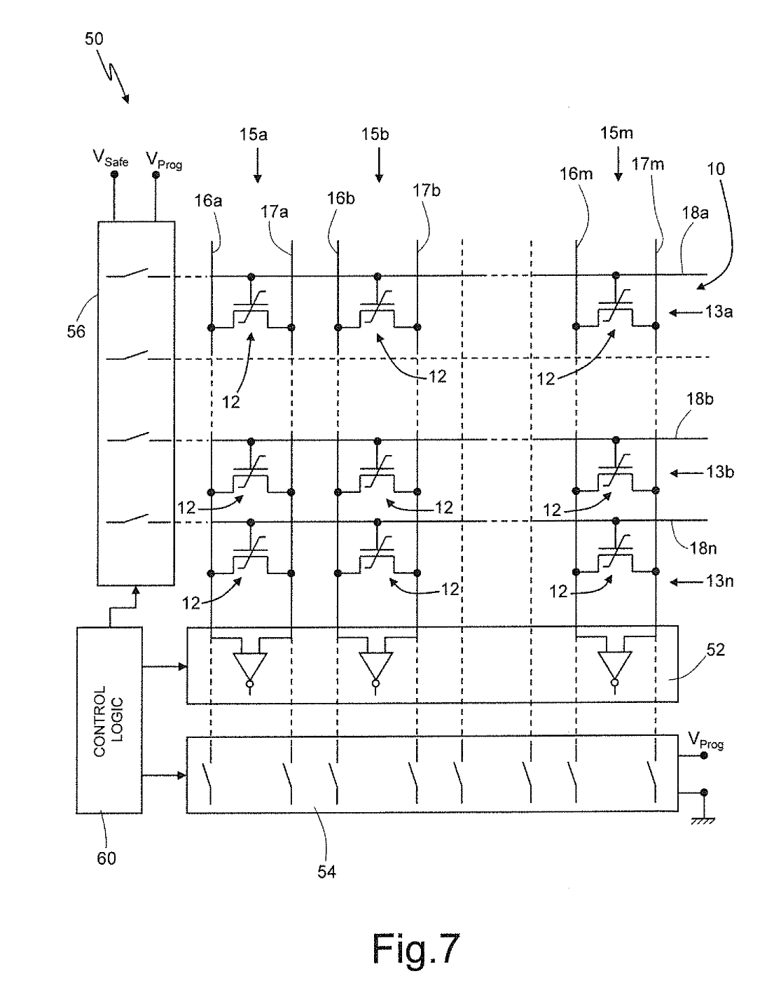

FIG. 7 shows steps of a further method for programming (writing) memory cells of the memory portion of FIG. 2;

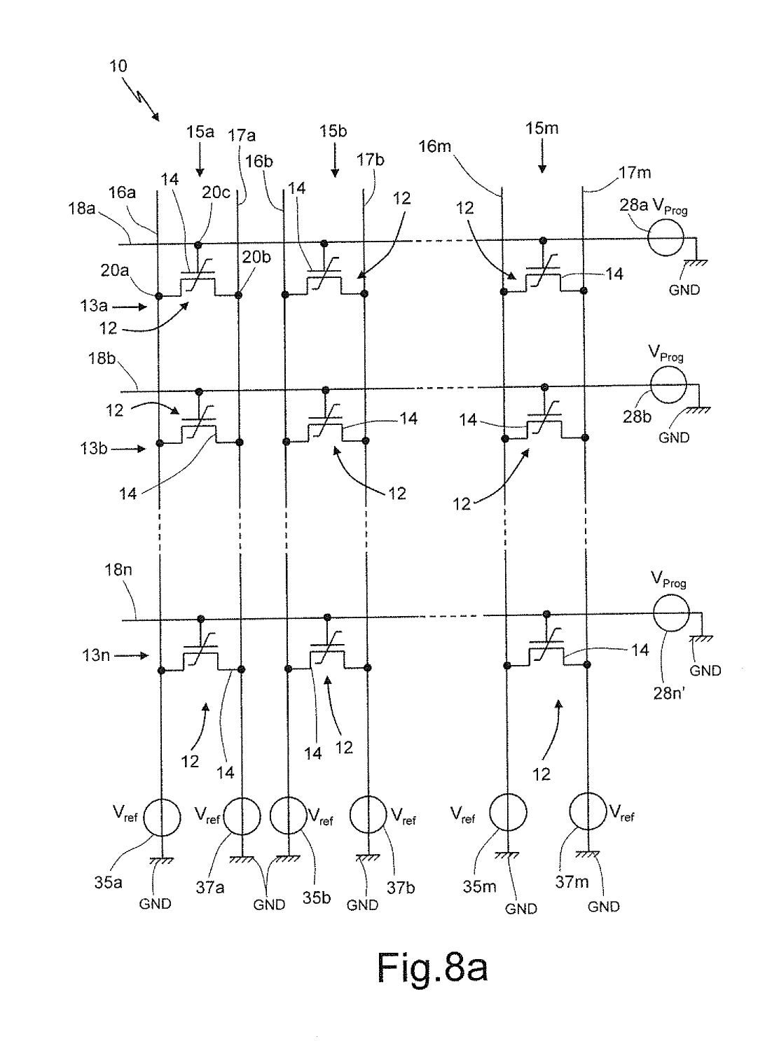

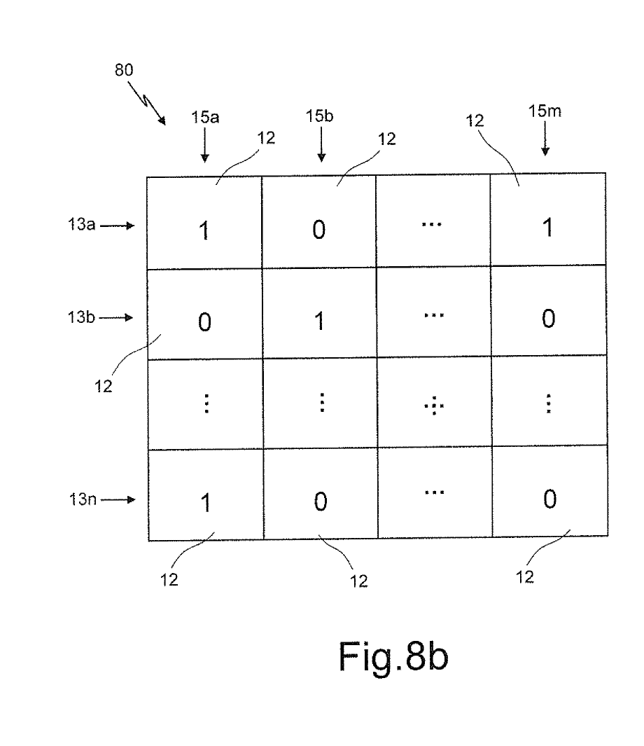

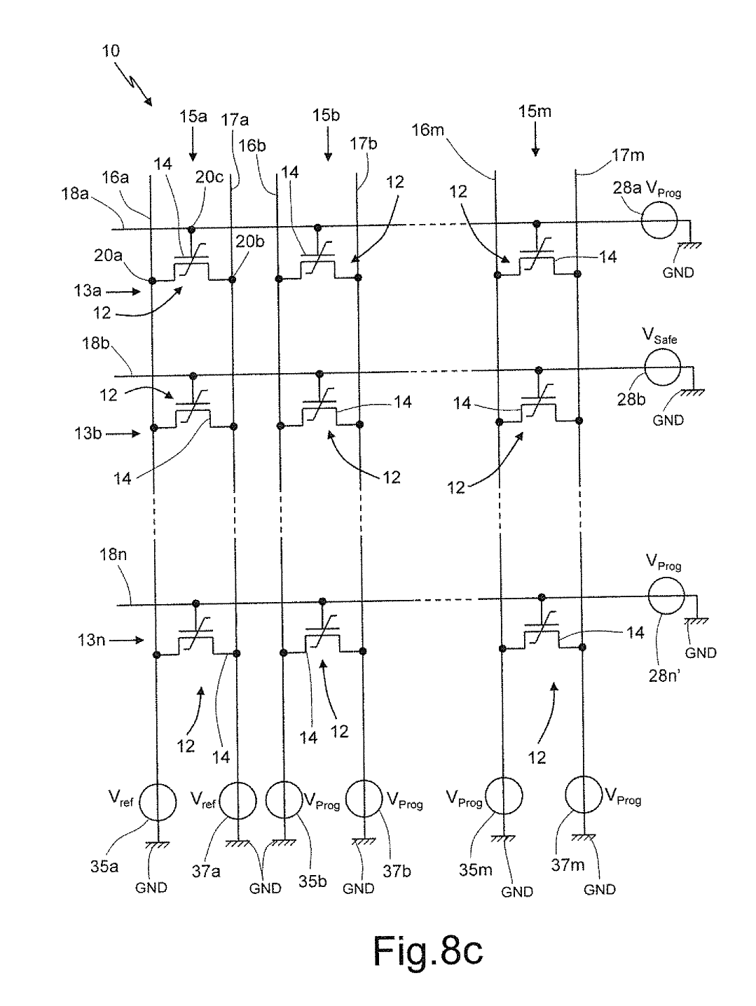

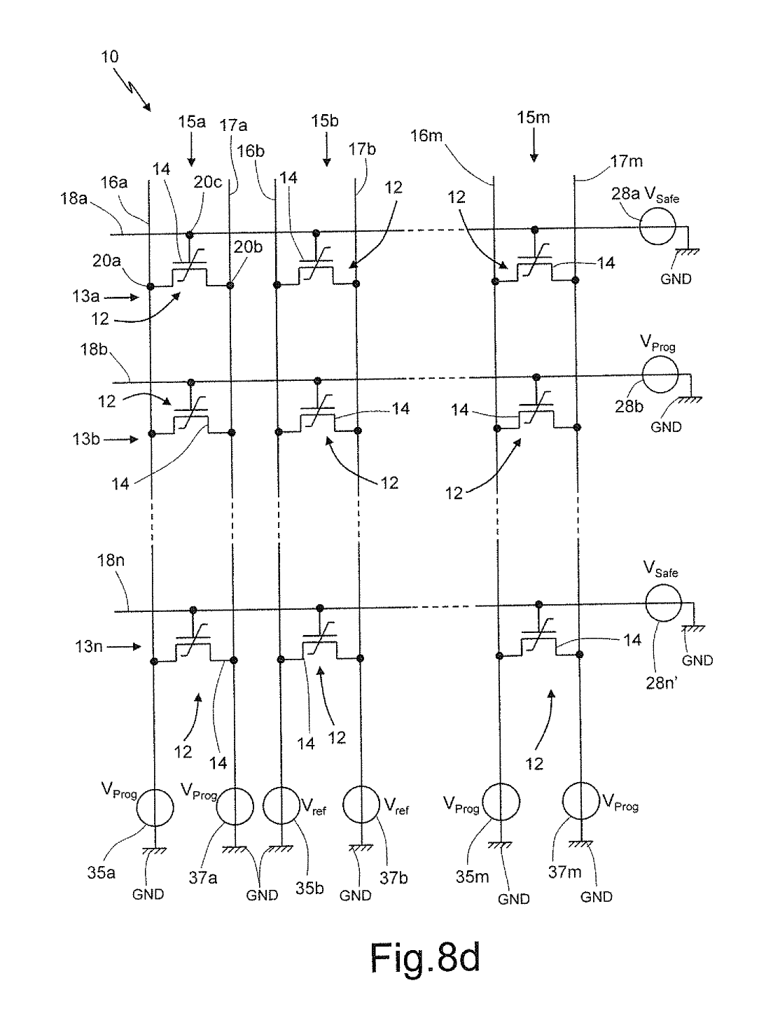

FIGS. 8a-8d show the memory portion of FIG. 2 during programming steps according to the method of FIG. 7;

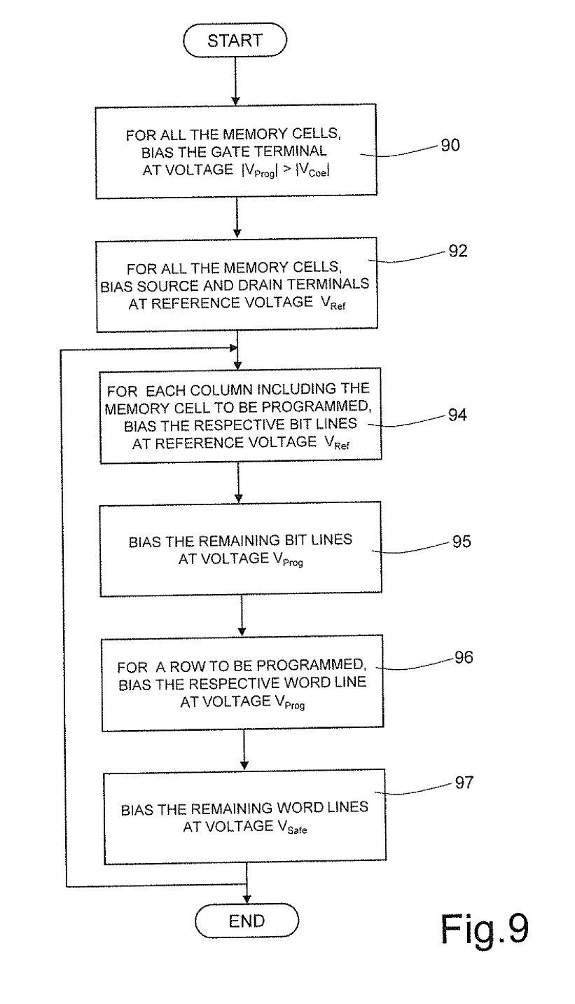

FIG. 9 shows steps of another method for programming (writing) memory cells of the memory portion of FIG. 2;

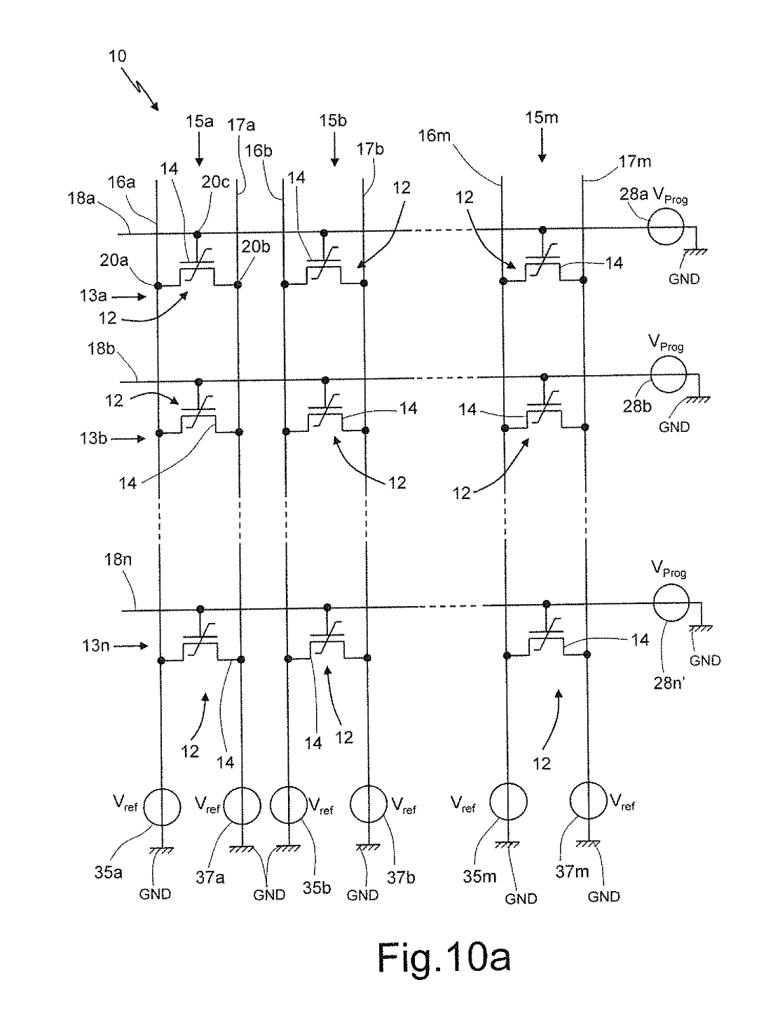

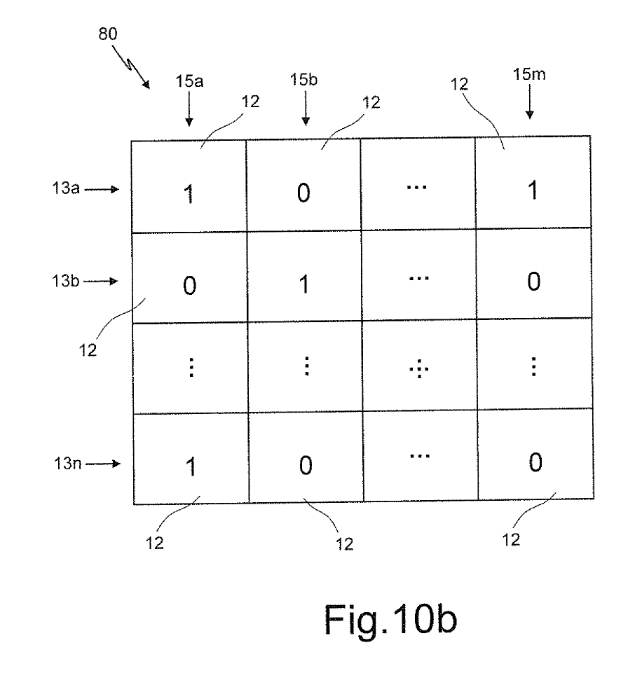

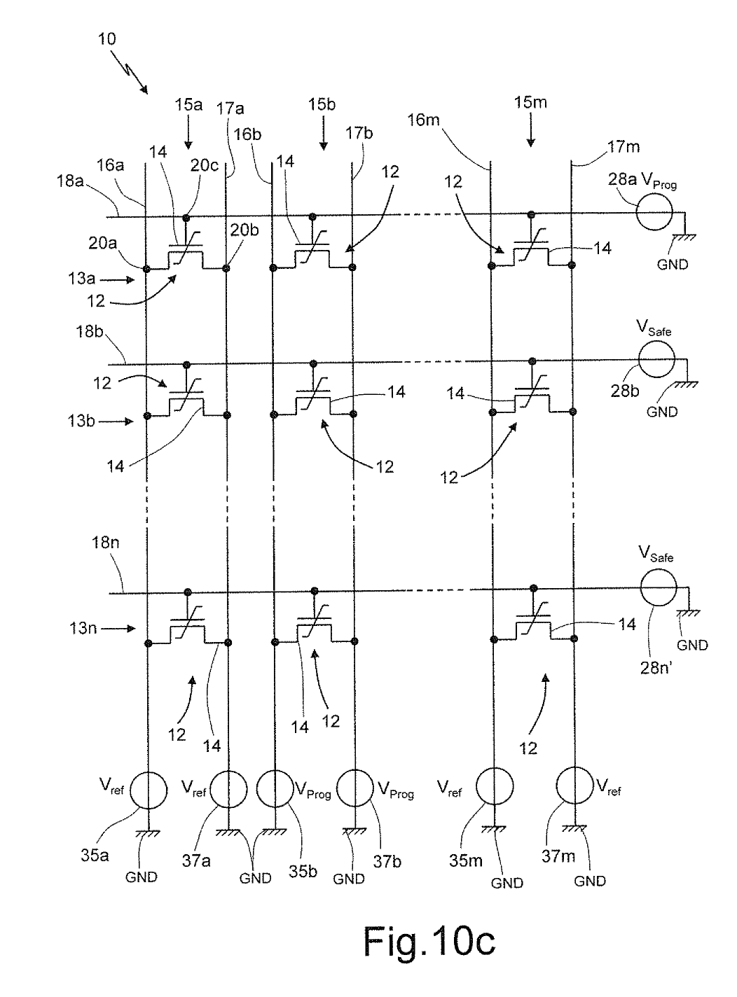

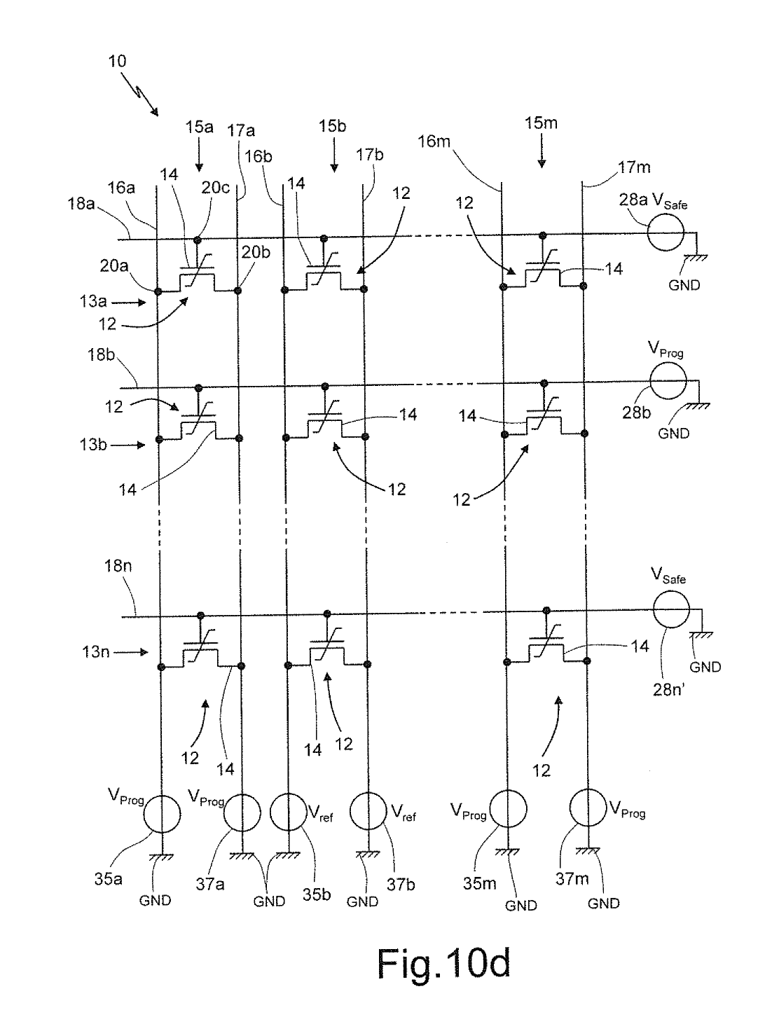

FIGS. 10a-10d show the memory portion of FIG. 2 during programming steps according to the method of FIG. 9;

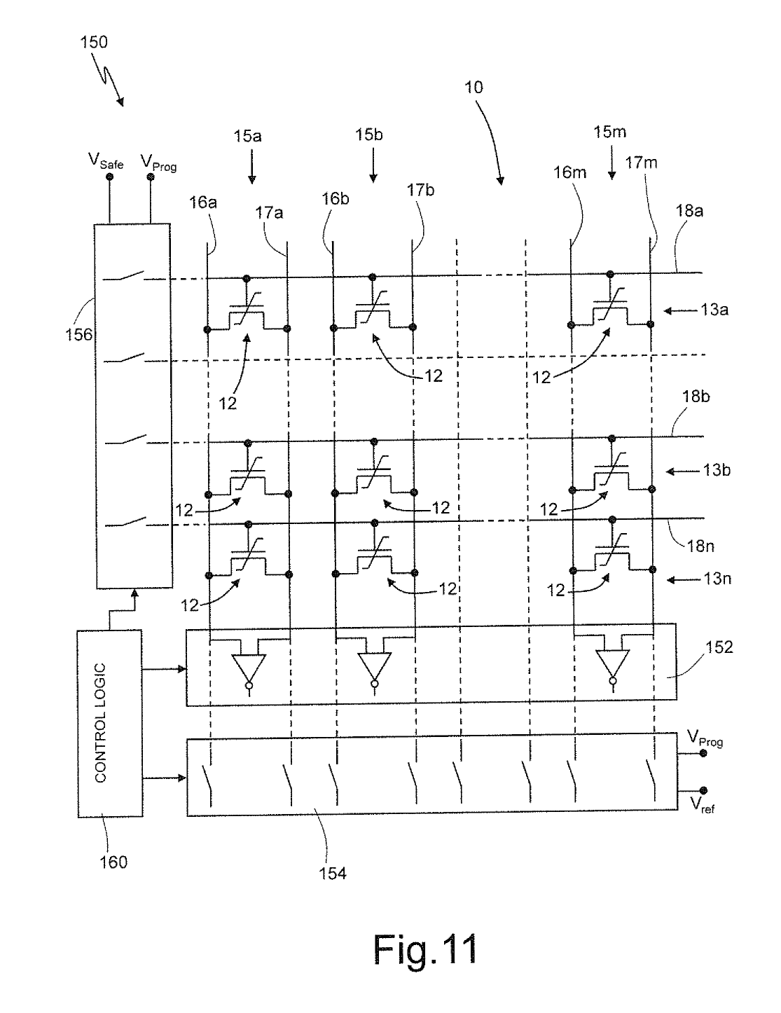

FIG. 11 shows a memory comprising the memory portion of FIG. 2; and

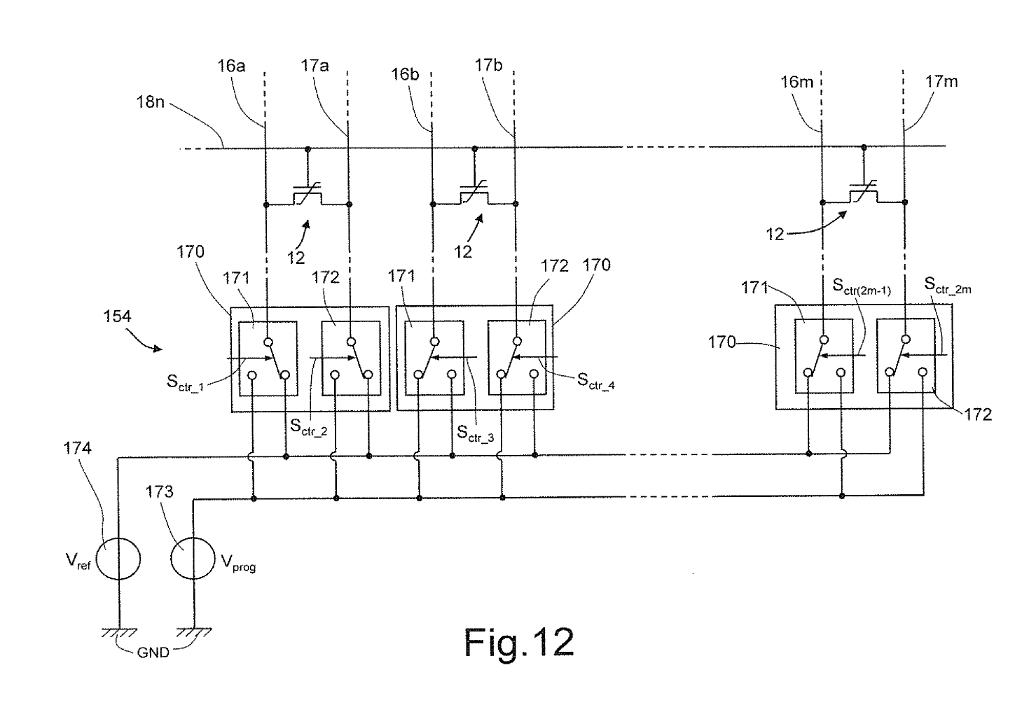

FIG. 12 shows in greater detail a portion of the column decoder of the memory of FIG. 11.

### DETAILED DESCRIPTION OF THE PREFERRED EMBODIMENTS

Designated by the reference number 10 in FIG. 2 is a portion of a memory (not shown as a whole) comprising a plurality of memory cells 12 arranged to form an array having a plurality of rows 13a, 13b, . . . , 13n and a plurality of columns 15a, 15b, . . . , 15m. Each row 13a-n of the array is defined by a respective word line 18a, 18b, 18n. Each column 15a-m of the array is instead defined by a respective pair of bit lines 16a-m and 17a-m. Each memory cell 12 is arranged at the intersection between a word line 18a-n and a pair of bit lines 16a-m, 17a-m, as described in greater detail below.

The memory portion 10 can comprise any number of rows and columns. In general, the memory portion 10 defines an array of memory cells 12 of dimensions (rows·columns) equal to n·m, with the n and m integer numbers being chosen as desired.

Each memory cell 12 comprises an electronic device that can be operated either as selector of the respective memory cell 12 (reading/writing of the memory cell 12) or as an element for storage of data (in particular, logic data 1 and 0). According to one embodiment, the above mentioned electronic device is a transistor 14, in particular, a FeFET (ferroelectric field-effect transistor) type. The memory cell 12 thus formed comprising a single FeFET is also known as a 1T memory cell. Each transistor 14 (FIGS. 3a-3c) has a first conduction terminal (source terminal) 20a, a second conduction terminal (drain terminal) 20b, and a control terminal (gate terminal) 20c. The transistors 14 belonging to the same column 15a-m have the respective first conduction terminals 20a connected to the same first bit line 16a, 16b, . . . , 16m, and the respective second conduction terminals 20b connected to the same second bit line 17a, 17b, . . . , 17c. In this way, for each column 15a-m, the transistors 14 are electrically connected to one another in parallel.

For each row 13a-n, the control terminals 20c of each transistor 14 belonging to that row 13a-n are electrically connected to the same word line 18a, 18b, . . . , 18n.

FIGS. 3a-3c show different embodiments of a FeFET that can be used as a memory cell 12 of the memory portion 10 of FIG. 2, and in particular, a single-transistor (1T) memory cell. FeFET transistors adapted to form 1T memory cells are, for example, disclosed in U.S. Pat. No. 6,091,621 and U.S. Pat. No. 6,335,550.

In particular, FIG. 3a shows, in a cross-sectional view, a transistor 14a of a FeFET type with a top gate structure. The transistor 14a comprises a semiconductor layer 22 made, for example, of organic material such as pentacene, anthracene, rubene or organic polymers, or alternatively, of an inorganic semiconductor material. A first conduction terminal 23 is made of conductive material and is designed to form a source terminal of the transistor 14a, and is to extend (at least partially) in the semiconductor layer 22. A second conduction terminal 24 is made of conductive material and is designed to form a drain terminal of the transistor 14a, and is to extend (at least partially) in the semiconductor layer 22 at a distance from the first conduction terminal 23 and is laterally connected to the first conduction terminal 23 by way of a portion 22a of the semiconductor layer 22.

A ferroelectric layer 26, preferably made of organic polymeric ferroelectric material (for example, polyvinylidene fluoride—PVDF-TrFE), is formed in contact with the semiconductor layer 22 and is separated from the first and second conduction terminals 23, 24 by way of the semiconductor layer 22. A control terminal 27 (gate terminal) made of conductive material is formed on, and in contact with, the ferroelectric layer 26. In this way, the ferroelectric layer 26 extends between the control terminal 27 and the semiconductor layer 22 in which the first and second conduction terminals 23, 24 are formed. The ferroelectric layer 26 has, in use, the function of a memory element designed to store the logic data that is to be stored. The transistor 14a described can be used to form the memory cell 12. In this case, the first conduction terminal 23 corresponds to the terminal 20a, the second conduction terminal 24 corresponds to the terminal 20b, and the control terminal 27 corresponds to the terminal 20c of the transistor 14 of FIG. 2.

To operate the transistor 14a of FIG. 3a as a memory element, in particular for writing logic data, a voltage is applied across the control terminal 27 and the conduction terminals 23, 24 to modify the state of polarization of the ferroelectric layer 26. In particular, a first polarization state is associated to a first logic value, while a second polarization state is associated to a second logic value. The polarization state set remains in the ferroelectric layer 26 following removal of the applied voltage.

To read logic data stored in the memory element formed by the transistor 14a, a voltage is applied across the first and second conduction terminals 23, 24, and the current that flows between the terminals 23, 24 is detected. The current that flows between the first and second conduction terminals 23, 24 is affected by the state of polarization of the ferroelectric layer 26, and the current value detected can thus be associated to the logic value stored. With reference to FIG. 3a, the portion of the semiconductor layer 22 between the first and second conduction terminals 23, 24 has, in use during reading operations, the function of a channel region of the transistor 14a in which the charge carriers flow.

FIG. 3b shows, in cross-sectional view, a transistor 14b of a FeFET type, having a structure of a bottom-gate/top-contact type, according to an embodiment alternative to that of FIG. 3a. The transistor 14b of FIG. 3b comprises, similar to the transistor 14a of FIG. 3a (elements that are in common are designated by the same reference numbers): the control terminal 27 made of a conductive material having the function of a gate terminal of the transistor 14b; the semiconductor layer 22; the layer of ferroelectric material 2 which extends between the semiconductor layer 22 and the control terminal 27; the first conduction terminal 23 which extends on top of and in electrical contact with the semiconductor layer 22; and the second conduction terminal 24 which extends on top of and in electrical contact with the semiconductor layer 22 at a distance from the first conduction terminal 23. The embodiment of FIG. 3b differs from the embodiment of FIG. 3a in so far as the first and second conduction terminals 23, 24 do not extend within the semiconductor layer 22, but on top of and in contact with the semiconductor layer 22. Operation of the transistor 14b for writing and reading of logic data is similar to what has been described with reference to the transistor 14a of FIG. 3a. The transistor 14b can hence be used as a memory cell 12 in the memory portion 10 of FIG. 2.

FIG. 3c shows, in cross-sectional view, a transistor 14c of a FeFET type having a structure of the bottom-gate type according to a further embodiment alternative to the one shown in FIGS. 3a and 3b. The transistor 14c of FIG. 3c has a structure similar to that of the transistor 14b of FIG. 3b, but differs from the latter on account of the presence of a semiconductor layer 22, which extends underneath, between, and on top of the first and second contact terminals 23, 24. To access the first and second conduction terminals 23, 24, appropriate contacts (not shown) need to be formed, which extend through the portion of the semiconductor layer formed on top of the first and second conduction terminals 23, 24. Operation of the transistor 14c, for writing and reading of logic data, is similar to what has been described with reference to the transistor 14a of FIG. 3a. The transistor 14c can be used as a memory cell 12 in the memory portion 10 of FIG. 2.

FIG. 4 shows an example of transcharacteristic curve for a FeFET. The axis of the abscissa (horizontal) represents the voltage V_{G} applied to the gate terminal of the FeFET, while the axis of the ordinate (vertical, in logarithmic scale) represents the current I_{D} that flows between the source terminal and the drain terminal as the voltage V_{G} varies (or vice versa, adopting the appropriate conventions on the sign of the current). A voltage value V_{G}≈V_{cc}<V_{coe} corresponds to the setting of a first predetermined stable state of polarization of the ferroelectric layer of the FeFET transistor. This corresponds to a value of current I_{D} that is minimum in absolute value. This can be associated to the low logic value (0). A voltage value V_{G}≈(−V_{cc})<(−V_{coe}) corresponds to the setting of a second predetermined stable state of polarization of the ferroelectric layer of the FeFET transistor (opposite to the first polarization state). This corresponds to a value of current I_{D} that is maximum in absolute value, which can be associated to the high logic value (1).

The association between the first stable polarization state and the low logic value and between the second stable polarization state and the high logic value is arbitrary. Alternatively, it is possible to associate the first stable polarization state to the high logic value, and the second stable polarization state to the low logic value. The transition between the two stable polarization states follows a hysteresis curve, as already discussed with reference to FIG. 1.

FIG. 5 shows, by way of a flowchart, steps for programming (writing) a memory comprising a plurality of memory cells. Each memory cell is of the 1T type, i.e., comprising a single transistor of a FeFET type (for example, according to the types shown in FIGS. 3a-3c or, indifferently, having a structure other than the ones shown).

The programming steps of FIG. 5 are described with joint reference to FIG. 6, which shows voltage signals applied to the memory portion 10 of FIG. 2 during the programming steps.

At a programming step, a memory cell 12 to be programmed is chosen. This may be, for example, with reference to FIG. 6, the memory cell 12 that is at the intersection of the first row 13a with the first column 15a, coupled to the word line 18a and the bit lines 16a, 17a. The step of choosing a memory cell 12 may be a step of deciding (e.g., using a microcontroller) which memory cell 12 the steps 30 and 34 are to be applied according to FIG. 5. The reasons and considerations behind this decision are not part of the present invention, and will not be further discussed. Then (step 30) the word line 13a is biased at a programming voltage V_{prog} (in particular, to limit the number of the supply voltages used, V_{prog} may be chosen equal to ±V_{cc} according to the logic data 1 or 0 to be written) so as to bias the control terminal 20c of the respective transistor 14 at the programming voltage V_{prog}. In FIG. 6, this step is illustrated by way of the voltage generator 28a connected to the word line 18a. In more detail, the voltage generator 28a is shown connected between a ground terminal GND and the word line 18a, and is configured for generating the programming voltage V_{prog}.

The programming voltage V_{prog} has the function of programming (writing) the memory cell 12 and is higher, in absolute value, than the coercive voltage V_{coe} of the ferroelectric material of the transistor 14 belonging to the memory cell 12 considered. The coercive voltage V_{coe} can have a positive or negative value, according to the logic value that is to be stored (written) in the memory cell 12. According to an embodiment of the present invention, the high logic value (1) is written in the considered memory cell 12 when V_{prog}≈(−V_{cc})<(−V_{coe}). The low logic value (0) is written in the considered memory cell 12 when V_{prog}≈(+V_{cc})>(+V_{coe}). In both cases, |V_{prog}|≈|±V_{cc}|>|±V_{coe}|. In more general terms, one should have a programming voltage V_{prog} higher, in modulus, than the coercive voltage value V_{coe}.

The remaining word lines 13b, . . . , 13n are biased (step 32) at a voltage V_{safe}, in an absolute value between 0 and V_{cc} (0<|V_{safe}|<|±V_{cc}|), for example, V_{safe}≈(±V_{cc}/2). For negative values of V_{coe}, V_{prog}<V_{coe} and −V_{cc}<V_{safe}<0 (e.g., V_{safe}=−V_{cc}/2), whereas for positive values of V_{coe} we have V_{prog}>V_{coe} and 0<V_{safe}<+V_{cc} (e.g. V_{safe}=+V_{cc}/2). With reference to FIG. 6, this step is illustrated showing voltage generators 28b, 28n, which are each connected between a ground terminal GND and a respective word line 18b-n and are configured for generating a voltage V_{safe}.

For carrying out programming of the memory cell 12, the corresponding bit lines (with reference to FIG. 6, for the case considered), the bit lines 16a and 17a are biased (step 34) at a reference voltage V_{ref}. For example, V_{ref} is the ground voltage GND (indicatively equal to 0 V). In this way, the source and drain terminals 20a, 20b of the corresponding transistor 14 are biased at the value of the reference voltage V_{ref}. In FIG. 6, this situation is shown schematically with generators 35a, 37a configured for generating the reference voltage V_{ref}. In the case, where the reference voltage V_{ref} is equal to the ground voltage GND, the bit lines 16a and 17a are directly connected to the ground voltage GND. A voltage equal to V_{prog}−V_{ref} is consequently applied between the gate terminal 20c and the source and drain terminals 20a and 20b of the respective transistor 14. In the case of the example where V_{ref}=0 V, the voltage V_{prog}−V_{ref} is equal to the programming voltage V_{prog}. Since the programming voltage V_{prog} has a value to set a stable state of polarization of the ferroelectric material of the ferroelectric layer 26 of the transistor 14, writing of the logic data in the memory cell 12 considered is thus performed. In general, the voltage value (V_{prog}−V_{ref}) needs to be higher than the value of coercive voltage V_{coe}, so as to set a stable state of polarization of the ferroelectric material of the ferroelectric layer 26 of the transistor 14.

During step 34, the source and drain terminals 20a, 20b of all the other transistors 14 connected to the bit lines 16a and 17a are biased at the voltage V_{ref}=0 V. The voltages V_{ref} and V_{safe} are chosen in such a way that the difference of potential V_{safe}−V_{ref} that is set up between the source (drain) terminals 20a (20b) and the gate terminal 20c of the transistors 14 connected between the bit lines 16a and 17a and the respective word line 18b-n is not sufficient to modify in a stable way the state of polarization of the ferroelectric material of the respective transistors 14 (i.e., |V_{safe}|−|V_{ref}|<|V_{coe}|). The memory cells 12 corresponding to the transistors 14 are not programmed during step 34, and maintain the logic data stored therein.

To prevent undesirable programming of the memory cells 12 arranged forming the rows 15b, 15m, the remaining bit lines 16b-m, 17b-m are biased at a voltage equal to the programming voltage V_{prog} (by way of a respective plurality of m−1 voltage generators 35b-m, 37b-m, as shown in FIG. 6).

For some transistors 14, the difference of potential between the respective gate terminal 20c and source/drain terminals 20a, 20b is zero (V_{prog}−V_{prog}.0 V). For other transistors 14, the difference of potential is equal to V_{safe}−V_{prog}. Other transistors are equal to V_{safe}−V_{ref}. In all cases, the voltage value that is set up between the gate terminal 20c and source/drain terminals 20a, 20b of the transistors 14 is less than the value of coercive voltage V. Consequently, the memory cells 12 are not programmed and maintain their own logic data stored therein. Only the transistor 14 whose gate terminal 20c is biased at the programming voltage V_{prog} and whose source/drain terminals 20a, 20b are biased at the reference voltage V_{ref} is programmed. This transistor 14 is the one coupled to the word line 18a and to the bit lines 16a, 17a. When V_{prog}=+V_{cc} and V_{ref}=0V (provided that V^{cc}>V_{coe}), the logic data 0 is written in the considered transistor 14. Otherwise, when V_{prog}=−V_{cc} and V_{ref}=0V (provided that −V_{cc}<−V_{coe}), the logic data 1 is written in the considered transistor 14.

The steps described with reference to FIG. 5 are executed iteratively for all the memory cells 12 that are to be programmed. Once programming of one memory cell 12 has been terminated, control passes from step 36 to step 32, and a new memory cell 12 is programmed.

According to an embodiment, the steps of the programming method of FIG. 5 (biasing of bit and word lines) are preferably executed simultaneously to prevent undesirable programming of some or all of the memory cells 12.

Alternatively, according to a further embodiment, it is possible to bias all the bit lines to a value V_{prog}, and simultaneously, all the word lines to a value V_{safe}, and then reduce to V_{ref}0 V the biasing value of the bit lines corresponding to the memory cell 12 to be programmed and increase the biasing of the value V_{safe} to the value V_{prog}.

The reference value V_{ref} is, according to an embodiment, equal to 0 V, but in general it is a reference value that may be other than 0 V. In general, one should have a voltage drop, across a memory cell 12, higher than the coercive voltage V_{coe}(|V_{prog}|−|V_{ref}|>|V_{coe}|) in order to have that memory cell 12 programmed.

If all the memory cells 12 of the memory portion 10 are to be programmed, it is advantageous to program one memory cell 12 at a time in a sequential and progressive way for columns 15a-m. For example, programming of the memory cell 12 at the intersection between the row 13a and the column 15a is first performed, and once programming of this memory cell 12 has been completed, programming of the cell arranged on the same column but at the next row is carried out (row 13b, column 15a), and so on up to complete programming of the n cells present at the column 15a. Next, programming of the subsequent column is carried out, i.e., of the memory cell 12 at the intersection between the row 13a and the column 15b, and so on, in a sequential way, column by column, until the memory cells 12 of the m-th column are programmed.

The sequential and progressive way to program the memory portion 10 may be applied to program some or all of the m cells of a same row, and then, passing to the next row up to completion of the programming of the entire memory portion 10.

FIG. 7 shows, by way of a flowchart, steps for programming (writing) a memory comprising a plurality of memory cells. Each memory cell is of the 1T type, i.e., comprising a single transistor of a FeFET type (e.g., according to the types shown in FIGS. 3a-3c, or indifferently, having a structure other than the ones shown), according to a further embodiment.

The programming steps of FIG. 7 are described with joint reference to FIGS. 8a-8d, which show voltage signals applied to the memory portion 10 of FIG. 2 during programming of the method of FIG. 7.

As a first step (step 70) for all the memory cells 12 of the memory portion 10, the control terminal 20c of the respective transistors 14 is biased at a programming voltage V_{prog}. This is shown in FIG. 8a by having the voltage generators 28a, 28b, . . . , 28n configured to supply a programming voltage V_{prog} to the word lines 18a-n. Then (step 72), for all the memory cells 12 of the memory portion 10, the source and drain terminals 20a, 20b of the respective transistor 14 are biased at the reference voltage V_{ref}. This is shown in FIG. 8a by having the voltage generators 35a-m and 37a-m, configured to supply a reference voltage V_{ref} to the bit lines 16a-m and 17a-m. In this way, a first logic data is written in all of the memory cells 12 of the memory portion 10. For example, the first logic data is the logic data 0. Accordingly, the programming voltage V_{prog} is equal to +V_{cc} and the reference voltage V_{ref} is equal to GND (e.g., 0 V). In general, the voltage drop V_{prog}−V_{ref} on each transistor 14 is higher than the coercive voltage V_{coe}, so as to set a stable state of polarization of the ferroelectric material of the ferroelectric layer 26 of the transistor 14.

Then (steps 74 and 75) a second logic data 1 is written only in those memory cells 12 in which it is so required. For example, FIG. 8b shows, by way of a table 80, the required programming of the memory portion 10. Each box of the table 80 corresponds to a memory cell 12. In greater detail, a logic data 1 is to be written in: the memory cell 12 arranged in the first column 15a and first row 13a; the memory cell 12 arranged in the first column 15a and n-th row 13a; the memory cell 12 arranged in the second column 15b and second row 13b; and the memory cell 12 arranged in the m-th column 15m and first row 13a.

The programming of the memory cells 12 is carried out column-by-column. To this end, as shown in FIG. 8c, the memory cells 12 in the first column 15a are programmed by supplying the reference voltage V_{ref} to the bit lines 16a and 17a (step 74), while the remaining bit lines 16b-m, 17b-m are biased at the programming voltage V_{prog}=−V_{cc} (step 75). The word lines 18a and 18n, coupled to the memory cells 12, belonging to the first column 15a, to be programmed at the logic level 1, are biased at the programming voltage V_{prog}=−V_{cc} (step 76). As a consequence, a voltage drop equal to V_{prog}=(−V_{cc})<(−V_{coe}) is set across the memory cells 12 arranged between the word line 18a and the bit lines 16a, 17a, and between the word line 18n and the bit lines 16a, 17a. A stable state of polarization of the ferroelectric material of the ferroelectric layer 26 of the respective transistors 14 is thus set. In detail, the polarization state of the selected transistors 14 is changed in such a way that the logic data 1 is written therein.

To avoid an undesired programming of the remaining memory cell 12 of the first column 15a, the word line 18b is supplied (step 77) with the voltage V_{safe} (e.g., equal to −V_{cc}/2).

The supplying of the above mentioned voltages to the bit lines 16a-m, 17a-m, and word lines 18a-n, is carried out at the same instant in time for all of them to avoid spurious programming of memory cells 12 other than those to be programmed. In contrast to the method described with reference to FIGS. 5 and 6, according to this embodiment, the entire first column 15a is programmed with less programming steps.

Then, the second column 15b can be programmed, as shown in FIG. 8d (coming back to step 74 of FIG. 7). The programming steps for the second column 15b conform substantially with those described with reference to the programming of the first column 15a. In more detail, the second column 15b is programmed by supplying the reference voltage V_{ref} to the bit lines 16b and 17b, while the remaining bit lines 16a, 17a, 16m, 17m are biased at the programming voltage V_{prog}=−V_{cc}. The word line 18b, coupled to the memory cell 12 to be programmed at the logic level 1, is biased at the programming voltage V_{prog}=−V_{cc}, thus writing the logic data 1 in the memory cell 12 coupled between the word line 18b and the bit lines 16b, 17b. To avoid an undesired programming of the remaining memory cells 12 of the second column 15b, the word lines 18a and 18n are biased with the voltage V_{safe} (e.g., equal to −V_{cc}/2).

The supplying of the above mentioned voltages to the bit lines 16a-m, 17a-m, and word lines 18a-n, is carried out at the same instant in time for all of them to avoid spurious programming of memory cells 12 other than the one (or those) to be programmed.

Alternatively, it is possible to bias all the bit lines to the value V_{prog}, and simultaneously, all the word lines to the value V_{safe}. It is also possible to reduce to V_{ref} the biasing voltage of the bit lines belonging to the column to be programmed, and increase the biasing voltage of the word line coupled to the memory cells to be programmed from the value V_{safe} to the value V_{prog}.

Then, the n-th column 15n can be programmed, by following the same teaching disclosed with reference to the first and second column 15a, 15b.

The advantages of the method according to FIGS. 7 and 8a-8d are evident. In particular, the programming time is considerably reduced with respect to the sequential programming method of FIGS. 5 and 6, since an entire column of the memory portion 10 can be written at once. Moreover, a lower number of voltages to be supplied to the word and bit lines is desired (the V_{safe}=+V_{cc}/2 voltage is not required).

According to another embodiment, the first logic data is 1 and the second logic data is 0. Accordingly, the programming voltage V_{prog} for writing the second logic data in the memory cells 12 is equal to +V_{cc} and the voltage V_{safe} is equal to +V_{cc}/2. In this case, the memory portion 10 is first initialized by writing the logic data 1 in all of the memory cells 12 of the memory portion 10, and then the logic data 0 is written column-by-column in those memory cells 12 where required. The programming steps are analogous to those described with reference to FIG. 7 and FIGS. 8a-8d.

The reference value V_{ref}, according to one embodiment, is equal to 0 V, but in general, it is a reference value that may be other than 0 V, provided that |V_{prog}|−|V_{ref}|>|V_{coe}|.

FIG. 9 shows, by way of a flowchart, steps for programming (writing) a memory comprising a plurality of memory cells. Each memory cell is of the 1T type, i.e., comprising a single transistor of a FeFET type (for example according to the types shown in FIGS. 3a-3c, or indifferently, having a structure other than the ones shown).

The programming steps of FIG. 9 are described with joint reference to FIGS. 10a-10d, which show voltage signals applied to the memory portion 10 of FIG. 2 during programming steps of the method of FIG. 9.

As a first step (step 90) for all the memory cells 12 of the memory portion 10, the control terminal 20c of the respective transistors 14 are biased at a programming voltage V_{prog}. This is shown in FIG. 10a by having the voltage generators 28a, 28b, . . . , 28n configured to supply a programming voltage V_{prog} to the word lines 18a-n. Then (step 92), for all the memory cells 12 of the memory portion 10, the source and drain terminals 20a, 20b of the corresponding transistor 14 are biased at the reference voltage V_{ref}. This is shown in FIG. 10a by having the voltage generators 35a-m and 37a-m configured to supply the reference voltage V_{ref} to the bit lines 16a-m and 17a-m. In this way, a first logic data is written in all of the memory cells 12 of the memory portion 10. For example, the first logic data is the logic data 0. Accordingly, the programming voltage V_{prog} is equal to +V_{cc} and the reference voltage V_{ref} is equal to GND (e.g., 0 V), In general, the voltage value (V_{prog}−V_{ref}) is higher (in modulus) than the value of coercive voltage V_{coe}. This sets a stable state of polarization of the ferroelectric material of the ferroelectric layer 26 of the transistor 14.

Then (step 94) a second logic data 1 is written only in those memory cells 12 in which it is so required. For example, FIG. 10b shows, by way of a table 100, the logic data to be written in each one of the memory cells 12 of the memory portion 10. Each box of the table 100 corresponds to a memory cell 12. In greater detail, according to this example, a logic data 1 is to be written in: the memory cell 12 arranged in the first column 15a and first row 13a; the memory cell 12 arranged in the first column 15a and n-th row 13n; the memory cell 12 arranged in the second column 15b and second row 13b; and the memory cell 12 arranged in the m-th column 15m and first row 13a.

The programming of the memory cells 12 is carried out row-by-row. To this end (FIG. 10c), the memory cells 12 in the first row 13a are programmed by supplying the reference voltage V_{ref} to the bit lines 16a, 17a, and to the bit lines 16m, 17m (step 94). The remaining bit lines 16b, 17b are biased (step 95) at the programming voltage V_{prog}=−V_{cc}. The word line 18a, coupled to the memory cells 12 to be programmed at the logic level 1 is biased at the programming voltage V_{prog}=−V_{cc} (step 96). In this way, the logic data 1 is written in the memory cells 12 coupled between the word line 18a and each of the bit lines 16a, 17a, and coupled between the word line 18a and each of the bit lines 16m, 17m (a voltage drop equal to V_{prog} is set across the respective transistor 14, thus changing its polarization state). The memory cell 12 coupled between the word line 18a and the bit lines 16b, 17b is not programmed (a voltage drop equal to 0 V is set across the respective transistor 14) and retains its previous polarization state (logic data 0). To avoid an undesired programming of the remaining memory cells 12 of the memory portion 10, the word lines 18b-n are biased (step 97) at the voltage V_{safe} (e.g., equal to −V_{cc}/2).

Then, in FIG. 10d, the second row 13b can be programmed. The programming steps of the second row 13b conform substantially with those described with reference to the programming of the first row 13a. In more detail, the second row 13b is programmed by supplying the reference voltage V_{ref} to the bit lines 16b and 17b, while the remaining bit lines 16a, 17a, 16m, 17m are biased at the programming voltage V_{prog}=−V_{cc}. The word line 18b, coupled to the memory cell 12 to be programmed at the logic level 1, is biased at the programming voltage V_{prog}=−V_{cc}, thus writing therein the logic data 1. To avoid an undesired programming of the remaining memory cells 12 of the second row 13b, the bit lines 16a, 17a and 16m, 17m are biased at the programming voltage V_{prog}=−V_{cc}. To avoid an undesired programming of the remaining memory cells 12 of the memory portion 10, the word lines 18a, 18n are biased at the voltage V_{safe} (e.g., equal to −V_{cc}/2).

Then, the n-th row 13n can be programmed, by following the same teaching disclosed with reference to the first and second rows 13a, 13b.

The supplying of the above mentioned voltages to the bit lines 16a-m, 17a-m, and word lines 18a-n, is carried out at the same instant in time for all of them to avoid spurious programming of memory cells 12 other than the those to be programmed. Alternatively, it is possible to bias all the bit lines to the voltage V_{prog}, and simultaneously, all the word lines to the voltage V_{safe}. There is a reduction to V_{ref} for the biasing value of the bit lines coupled to the memory cells 12 to be programmed. The biasing voltage of the word line coupled to the memory cells 12 to be programmed is increased from the value V_{safe} to the value V_{prog}.

The advantages of the method according to FIGS. 9 and 10a-10d are evident. In particular, the programming time is considerably reduced with respect to the sequential programming method of FIGS. 5 and 6, since an entire row of the memory portion 10 can be written at once (e.g., see FIG. 10c). Moreover, a lower number of voltages may be required to be supplied to the word and bit lines (the voltage V_{safe}=+V_{cc}/2 is not required).

According to another embodiment, the first logic data is 1, and the second logic data is 0. Accordingly, the programming voltage V_{prog} for writing the second logic data in the memory cells 12 is equal to +V_{cc} and the voltage V_{safe} is equal to +V_{cc}/2. In this case, the memory portion 10 is first initialized by writing the logic data 1 in all the memory cells 12 of the memory portion 10, and then the logic data 0 is written row-by-row in those memory cells 12 where it is required. The programming steps are analogous to those described with reference to FIG. 9 and FIGS. 10a-10d.

The reference value V_{ref}, according to one embodiment, is equal to 0 V, but in general, it is a reference value that may be other than 0 V, provided that |V_{prog}|−|V_{ref}|>|V_{coe}|.

According to a further embodiment, the step 90 described with reference to FIGS. 9 and 10a may be carried out by biasing at the reference voltage V_{ref} the control terminal 20c of all of the transistors 14 belonging to the memory cells 12 of the memory portion 10. This corresponds to supplying a V_{ref} voltage to all of the word lines 18a-n. At the same time, all the bit lines 16a-m, 17a-m are biased at a programming voltage V_{prog}. In this way, a first logic data is written in all of the memory cells 12 of the memory portion 10. For example, the first logic data is the logic data 0. Accordingly, the programming voltage V_{prog} is equal to −V_{cc} and the reference voltage V_{ref} is equal to GND (e.g., 0 V). Should the first logic data be chosen as the logic data 1, the programming voltage V_{prog} to be applied to the bit lines 16a-m, 17a-m would have been V_{prog}=+V_{cc}. The association of a certain polarization state of the ferroelectric layer 26 of a transistor 14 and a logic data 1 or 0 is arbitrary and may be chosen as needed.

In general, the voltage value (V_{prog}−V_{ref}) is higher (in modulus) than the value of the coercive voltage V_{coe}. This sets a stable state of polarization of the ferroelectric material of the ferroelectric layer 26 of the transistor 14.

FIG. 11 shows an architecture of a memory 150, which comprises the memory portion 10 of FIG. 2. The memory 150 comprises a reading block 152, and in particular, a plurality of sense amplifiers (even more in particular, a number of sense amplifiers equal to m). Each one is connected to the bit lines 16a-16m, 17a-17m of a respective column 15a-m, and is designed to be used during operations of reading of the memory 150. The reading operations do not form part of the present invention, and are not described herein.

The memory 150 further comprises a column decoder 154 connected to the bit lines 16a-16m, 17a-17m of each column 15a-m, and is adapted to connect the bit lines appropriately to voltage generators/ground references, which are configured for biasing. The biasing is according to the steps of the method of FIG. 5, or the method of FIG. 7, or the method of FIG. 9, wherein the bit lines 16a-16m, 17a-17m are to be biased to the required operating voltages (V_{prog} or V_{ref}), or to the ground reference voltage GND (e.g., 0 V).

The memory 150 further comprises a row decoder 156, connected to the word lines 18a-n of each row 13a-n, and is to connect the word lines appropriately to voltage generators configured for biasing, according to the steps of the method of FIG. 5, or the method of FIG. 7, or the method of FIG. 9, the word lines 18a-n to the operating voltages V_{prog}, V_{safe} or to the ground reference voltage GND.

The column decoder 154 and row decoder 156 comprise, for example, analog switches, such as single pole double throw (SPDT) switches. The latter can be integrated in pairs (DPDT—double pole double throw), in sets of three, or in sets of four in the same device.

FIG. 12 is a schematic illustration of a connection topology providing, by way of example, a possible implementation of the column decoder 154, and in particular, for connecting the bit lines to the operating voltages V_{prog} and V_{ref}, for implementing the steps of the method of FIG. 5 or the method of FIG. 7, or the method of FIG. 9.

FIG. 12 shows a portion of the column decoder 154 comprising a DPDT-switch block 170 coupled to each pair of bit lines 16a-m, 17a-m. Each DPDT-switch block 170 comprises two SPDT-switch sub-blocks 171 and 172, each of which is coupled to one of the bit lines 16a-m, 17a-m, and which are configured for alternatively coupling the respective bit line 16a-m, 17a-m to a voltage generator 173 to generate the voltage V_{prog} and to a voltage generator 174 to generate the voltage V_{ref}. In a basic embodiment, each SPDT-switch block 171, 172 comprises a switch configured for being controlled in switching by way of a respective external signal S_{ctr}_{_{—}}₁, S_{ctr}_{_{—}}₂, . . . , S_{ctr}_{_{—}}₂, generated, for example, by the control logic 160.

The row decoder 156 (not shown) has a structure similar to the column decoder 154 of FIG. 12, and is adapted to couple each word line 18a-n to the operating voltages V_{prog} and V_{safe} for implementing the method of FIG. 5, or the method of FIG. 7, or the method of FIG. 9.

The reading block 152, the row decoder 156, and the column decoder 154 are operatively connected to a control logic 160. The control logic 160 is in particular configured for controlling operation of the row decoder 156 and column decoder 154 to implement the steps of the method of FIG. 5, or the method of FIG. 7, or the method of FIG. 9.

From an examination of the characteristics provided according to the present disclosure, the advantages that it affords are evident. In particular, the writing method enables programming of a memory cell comprising a single FeFET through direct biasing of its terminals, at the same time controlling the voltages applied to the terminals of all the other memory cells. This eliminates any possible disturbance pulse from which the risk of an overwriting of the other memory cells would derive.

For what concerns the memory architecture based upon a single cell, the architecture presents the advantage of facilitating the implementation of the memory circuit at the level of a physical layout, limiting to a minimum the number of metal layers necessary and reducing the space occupied as compared to embodiments of a known type. Each memory cell comprises a selection transistor and a ferroelectric capacitor, physically separate from the selection transistor, for storing the logic data.

Finally, modifications and variations may be made to what has been described and illustrated herein without departing from the sphere of protection of the present invention, as defined in the annexed claims.

In addition, for the purposes of the present invention, the change of the state of polarization of the ferroelectric layer 26 can be obtained by biasing the bit lines 16a-m and 17a-m belonging to the same column 15a-m at voltages different from one another, but the difference of potential between the voltage applied to the gate terminal and the voltages applied to the source and drain terminals is such so as to generate a stable variation of the state of polarization of the ferroelectric layer 26 of the transistor 14 that is being written.

Moreover, the writing method according to the present invention does not require the presence of two bit lines 16a-m and 17a-m for each column 15a-m. In fact, for each column 15a-m, the single bit line 16a-m (or the single bit line 17a-m) is sufficient for generating a voltage drop between the gate terminal 20c and the source terminal 20a (or drain terminal 20b), partially biasing the ferroelectric layer 26 and causing a stable variation of the state of polarization of at least a portion of the ferroelectric layer 26 of the transistor 14 that is being written (thus varying the logic data stored therein).

1-38. (canceled)

39. A method for writing logic data in a memory comprising first, second and third biasing lines; a first memory cell comprising a first ferroelectric transistor comprising a layer of ferroelectric material, a first conduction terminal electrically coupled to the third biasing line, and a control terminal electrically coupled to the first biasing line; and a second memory cell comprising a second ferroelectric transistor comprising a layer of ferroelectric material, a first conduction terminal electrically coupled to the third biasing line, and a control terminal electrically coupled to the second biasing line, the method comprising:
a) supplying to the first biasing line a writing voltage to bias the control terminal of the first ferroelectric transistor to a first biasing value;
b) supplying to the second biasing line an intermediate voltage that is lower, in absolute value, than the writing voltage, to bias the control terminal of the second ferroelectric transistor to a second biasing value;
c) supplying to the third biasing line a reference voltage to bias the respective first conduction terminals of the first and the second ferroelectric transistors to a same third biasing value different from the first biasing value and the second biasing value; and
d) changing a polarization state of the layer of ferroelectric material of the first ferroelectric transistor only based on steps a)-c), so that the logic data is written in the first memory cell.

40. The method according to claim 39, wherein the layer of ferroelectric material of the first ferroelectric transistor and the layer of ferroelectric material of the second ferroelectric transistor have respective polarization states, and wherein step d) comprises changing the polarization state of the ferroelectric material of the first ferroelectric transistors while maintaining a polarization state of the ferroelectric material of the second ferroelectric transistor.

41. The method according to claim 40, wherein the layers of ferroelectric material of the first and the second ferroelectric transistors have a same coercive voltage; wherein changing the polarization state comprises applying, between the first conduction terminal and the control terminal of the first ferroelectric transistor, a voltage higher in absolute value than the same coercive voltage; and wherein maintaining the polarization state comprises applying, between the first conduction terminal and the control terminal of the second ferroelectric transistor, a voltage lower in absolute value than the same coercive voltage.

42. The method according to claim 39, wherein the memory further comprises a fourth biasing line; a third memory cell comprising a third ferroelectric transistor comprising a ferroelectric transistor comprising a layer of ferroelectric material, a first conduction terminal electrically coupled to the fourth biasing line, and a control terminal electrically coupled to the first biasing line, the method further comprising:
e) applying to the fourth biasing line the writing voltage to bias the first conduction terminal of the third ferroelectric transistor at the first biasing value.

43. The method according to claim 42, wherein the memory further comprises fifth and sixth biasing lines; wherein the first and the second ferroelectric transistors further comprise a respective second conduction terminal coupled to the fifth biasing line; and wherein the third ferroelectric transistor further comprising a respective second conduction terminal coupled to the sixth biasing line, the method further comprising:
f) supplying to the fifth biasing line the reference voltage to bias the second conduction terminals of the first and second ferroelectric transistors to the third biasing value; and
g) supplying to the sixth biasing line the writing voltage to bias the second conduction terminal of the third ferroelectric transistor at the first biasing value.

44. The method according to claim 39, wherein steps a), b), and c) are performed simultaneously.

45. The method according to claim 43, wherein steps a), b), c), e), f), g) are performed simultaneously.

46. The method according to claim 39, further comprising, prior to step c), supplying to the third biasing line the writing voltage to bias the respective first conduction terminals of the first and second ferroelectric transistors to the first biasing value.

47. The method according to claim 39, wherein the first and second biasing lines are configured as word lines of the memory, and the third biasing line is configured as a bit line of the memory.

48. A method for programming a memory comprising a plurality of word lines; a plurality of bit lines; and a plurality of memory cells coupled between respective word lines and bit lines, with each memory cell comprising a ferroelectric transistor comprising a conduction terminal coupled to a bit line among the plurality of bit lines, and a control terminal coupled to a word line among the plurality of word lines, with each ferroelectric transistor having a coercive voltage such that when a voltage higher than the coercive voltage is applied between the conduction terminal and the control terminal, a polarization state of the ferroelectric transistor is changed, the method comprising:
a) selecting a memory cell to be programmed from among the plurality of memory cells;
b) supplying a writing voltage to the word line coupled to the control terminal of the ferroelectric transistor of the selected memory cell;
c) supplying, to the other word lines of the plurality of word lines, an intermediate voltage that is lower, in absolute value, than the writing voltage;
d) supplying a reference voltage, different from the writing voltage and from the intermediate voltage, to the bit line coupled to the conduction terminal of the ferroelectric transistor of the selected memory cell, with the reference voltage and the writing voltage being chosen so that a voltage drop across the ferroelectric transistor of the selected memory cell is higher in absolute value than the coercive voltage in absolute value;
e) supplying the writing voltage to the bit lines other than the bit line coupled to the conduction terminal of the ferroelectric transistor of the selected memory cell, with the intermediate voltage and the writing voltage being chosen so that a voltage drop across the ferroelectric transistor of the selected memory cell is lower in absolute value than the coercive voltage in absolute value; and
f) repeating steps a) to e) for each memory cell to be programmed.

49. The method according to claim 48, wherein steps from b) to e) are performed simultaneously.

50. The method according to claim 48, further comprising, prior to step d), supplying to the bit line coupled to the conduction terminal of the ferroelectric transistor of the selected memory cell the writing voltage.

51. A method for programming a memory comprising a plurality of word lines; a plurality of bit lines; and a plurality of memory cells coupled between a respective word and bit line, with each memory cell comprising a ferroelectric transistor comprising a conduction terminal coupled to a bit line among the plurality of bit lines, and a control terminal coupled to a word line among the plurality of word lines, with each ferroelectric transistor having a coercive voltage such that when a voltage higher than the coercive voltage is applied between the conduction terminal and the control terminal, a polarization state of the ferroelectric transistor is changed, the method comprising:
a) supplying a first writing voltage to each word line of the plurality of word lines;
b) supplying a reference voltage, different from the first writing voltage, to each bit line of the plurality of bit lines, with the reference voltage and the first writing voltage being chosen so that a first polarization state is changed in the ferroelectric transistor of each memory cell;
c) selecting a bit line among the plurality of bit lines;
d) supplying the reference voltage to the selected bit line;
e) supplying a second writing voltage to each bit line other than the selected bit line;
f) selecting at least one word line coupled to at least one respective memory cell to be programmed, with the at least one memory cell to be programmed being further coupled to the selected bit line;
g) supplying an intermediate voltage to each word line other than the at least one selected word line, with the intermediate voltage and the second writing voltage being chosen so that the voltage drop across the ferroelectric transistors coupled to the word lines other than the selected at least one word line is lower in absolute value than the coercive voltage in absolute value;
h) supplying the second writing voltage to each of the selected word lines, with the second writing voltage and the reference voltage being chosen so that a voltage drop across the ferroelectric transistors coupled to both the selected word lines and the selected bit lines is higher in absolute value than the coercive voltage in absolute value so that a second polarization state is set different than the first polarization state in the ferroelectric transistors coupled to both the selected word lines and the selected bit lines; and
i) repeating steps from c) to h) for at least one more bit line.

52. The method according to claim 51, wherein steps from d) to g) are performed simultaneously.

53. A method for programming a memory comprising a plurality of word lines; a plurality of bit lines; and a plurality of memory cells coupled between a respective word and bit line, with each memory cell comprising a ferroelectric transistor comprising a conduction terminal coupled to a bit line among the plurality of bit lines, and a control terminal coupled to a word line among the plurality of word lines, with each ferroelectric transistor having a coercive voltage such that when a voltage higher than the coercive voltage is applied between the conduction terminal and the control terminal, a polarization state of the ferroelectric transistor is changed, the method comprising:
a) supplying a first writing voltage to each word line of the plurality of word lines;
b) supplying a reference voltage, different from the first writing voltage, to each bit line of the plurality of bit lines, with the reference voltage and the first writing voltage being chosen so that a first polarization state is changed in the ferroelectric transistor of each memory cell;
c) selecting a word line among the plurality of word lines;
d) supplying a second writing voltage to the selected word line;
e) selecting at least one bit line coupled to at least one respective memory cell to be programmed, with each memory cell to be programmed being further coupled to the selected word line;
f) supplying the second writing voltage to each bit line other than the at least one selected line;
g) supplying an intermediate voltage to each word line other than the selected word line, with the intermediate voltage and the second writing voltage being chosen so that a voltage drop across the ferroelectric transistors coupled to the word lines other than the selected word lines is lower than the coercive voltage value;
h) supplying the reference voltage to the at least one selected bit line, with the reference voltage and the second writing voltage being chosen so that the voltage drop across the ferroelectric transistors coupled to both the selected word line and the at least one selected bit line is higher than the coercive voltage, to set a second polarization state different than the first polarization state in the ferroelectric transistors coupled to both the selected word line and the at least one selected bit line; and
i) repeating steps d) and f) to h) for at least one more bit line.

54. The method according to claim 53, wherein steps d) to g) are performed simultaneously.

55. A ferroelectric memory comprising:
a plurality of biasing lines comprising a first biasing line, a second biasing line and a third biasing line;
a first memory cell comprising a first ferroelectric transistor comprising a layer of ferroelectric material, a first conduction terminal electrically coupled to said third biasing line, and a control terminal electrically coupled to said first biasing line;
a second memory cell comprising a second ferroelectric transistor comprising a layer of ferroelectric material, a first conduction terminal electrically coupled to said third biasing line, and a control terminal electrically coupled to said second biasing line;
a first generator electrically coupled to said control terminal of said first ferroelectric transistor through said first biasing line;
a second generator electrically coupled to said control terminal of said second ferroelectric transistor through said second biasing line; and
a third generator electrically coupled to said first conduction terminal of said first and second ferroelectric transistors through said third biasing line;
said first, second, and third generators configured to
a) supply to said first biasing line a writing voltage to bias said control terminal of said first ferroelectric transistor at a first biasing value,
b) supply to said second biasing line an intermediate voltage that is lower, in absolute value, than the writing voltage, to bias said control terminal of said second ferroelectric transistor to a second biasing value,
c) supply to said third biasing line a reference voltage to bias said respective first conduction terminals of said first and second ferroelectric transistors to a same third biasing value different from the first biasing value and the second biasing value, and
d) change a polarization state of the layer of ferroelectric material of said first ferroelectric transistor only based on steps a)-c), so that the logic data is written in said first memory cell.

56. The ferroelectric memory according to claim 55, wherein the layer of ferroelectric material of said first ferroelectric transistor and the layer of ferroelectric material of said second ferroelectric transistor have respective polarization states, and wherein step d) comprises changing the polarization state of the ferroelectric material of said first ferroelectric transistors while maintaining a polarization state of the ferroelectric material of said second ferroelectric transistor.

57. The ferroelectric memory according to claim 56, wherein the layers of ferroelectric material of said first and said second ferroelectric transistors have a same coercive voltage; wherein changing the polarization state comprises applying, between said first conduction terminal and said control terminal of said first ferroelectric transistor, a voltage higher in absolute value than the same coercive voltage; and wherein maintaining the polarization state comprises applying, between said conduction terminal and said control terminal of said second ferroelectric transistor, a voltage lower in absolute value than the same coercive voltage.

58. The ferroelectric memory according to claim 55, further comprising:
a fourth biasing line;
a third memory cell comprising a third ferroelectric transistor comprising a layer of ferroelectric material, a first conduction terminal electrically coupled to said fourth biasing line, and a control terminal electrically coupled to said first biasing line;
a fourth generator electrically coupled to said first conduction terminal of said third ferroelectric transistor through said fourth biasing line, and configured to apply to said fourth biasing line the writing voltage to bias said first conduction terminal of said third ferroelectric transistor at the first biasing value.

59. The ferroelectric memory according to claim 58 further comprising:
a fifth biasing line;
a sixth biasing line;
said first and second ferroelectric transistors further comprising a respective second conduction terminal coupled to said fifth biasing line, and said third ferroelectric transistor further comprising a respective second conduction terminal coupled to said sixth biasing line;
a fifth generator electrically coupled to said second conduction terminal of said first ferroelectric transistor through said fifth biasing line;
a sixth generator electrically coupled to said second conduction terminal of said second ferroelectric transistor through said sixth biasing line;
said fifth and sixth generators being configured to
supply to said fifth biasing line the reference voltage to bias said second conduction terminals of said first and the second ferroelectric transistors to the third biasing value, and
supply to said sixth biasing line the writing voltage to bias said second conduction terminal of said third ferroelectric transistor at the first biasing value.

60. The ferroelectric memory according to claim 59, wherein said first, second, and third generators are configured to operate simultaneously.

61. The ferroelectric memory according to claim 59, wherein said first, second, third, fourth, fifth, and sixth generators are configured to operate simultaneously.

62. The ferroelectric memory according to claim 59, wherein said first and second biasing lines are configured as word lines, and said third biasing line is configured as a bit line.

63. A ferroelectric memory comprising:
a plurality of word lines;
a plurality of bit lines;
a plurality of memory cells coupled between respective word lines and bit lines, with each memory cell comprising a ferroelectric transistor comprising a conduction terminal coupled to a bit line among said plurality of bit lines, and a control terminal coupled to a word line among said plurality of word lines, with each ferroelectric transistor having a coercive voltage so that when a voltage higher than the coercive voltage is applied between said conduction terminal and said control terminal, a polarization state of said ferroelectric transistor is changed;
a first plurality of generators electrically coupled to said control terminals of said ferroelectric transistors through a respective word line;
a second plurality of generators electrically coupled to said conduction terminals of said ferroelectric transistors through a respective bit line; and
a control logic operable to select a memory cell to be programmed among said plurality of memory cells;
said first and second plurality of generators being operable to:
a) supply a writing voltage to the word line coupled to said control terminal of said ferroelectric transistor of said selected memory cell,
b) supply, to the other word lines of said plurality of word lines, an intermediate voltage that is lower, in absolute value, than the writing voltage,
c) supply a reference voltage, different from the writing voltage and from the intermediate voltage, to said bit line coupled to said conduction terminal of said ferroelectric transistor of said selected memory cell, with the reference voltage and the writing voltage being chosen so that a voltage drop across said ferroelectric transistor of said selected memory cell is higher in absolute value than the coercive voltage in absolute value, and
d) supply the writing voltage to said bit lines other than said line coupled to said conduction terminal of said ferroelectric transistor of said selected memory cell, with the intermediate voltage and the writing voltage being chosen so that a voltage drop across said ferroelectric transistor of said selected memory cell is lower in absolute value than the coercive voltage value in absolute value.

64. The ferroelectric memory according to claim 63, wherein said first and second plurality of generators are configured to operate simultaneously.

65. A ferroelectric memory comprising:
a plurality of word lines;
a plurality of bit lines;
a plurality of memory cells coupled between a respective word and bit line, with each memory cell including a ferroelectric transistor having a conduction terminal coupled to a bit line among said plurality of bit lines, and a control terminal coupled to a word line among said plurality of word lines, each ferroelectric transistor having a coercive voltage such that when a voltage higher than the coercive voltage is applied between said conduction terminal and said control terminal, a polarization state of said ferroelectric transistor is changed;
a first plurality of generators electrically coupled to said control terminals of said ferroelectric transistors through a respective word line;
a second plurality of generators electrically coupled to said conduction terminals of said ferroelectric transistors through a respective bit line; and
a control logic configured to select at least one memory cell to be programmed by selecting at least one bit line among said plurality of bit lines and at least one word line among said plurality of word lines, with said at least one memory cell to be programmed being coupled to both the at least one selected word and bit lines;
said first and second plurality of generators being operable to
a) supply a first writing voltage to each word line of said plurality of word lines,
b) supply a reference voltage, different from the first writing voltage, to each bit line of said plurality of bit lines, with the reference voltage and the first writing voltage being chosen so that a first polarization state is set in said ferroelectric transistor of each memory cell,
c) supply the reference voltage to the at least one selected bit line,
d) supply a second writing voltage to each bit line other than the at least one selected bit line,
e) supply an intermediate voltage to each word line other than the at least one selected word line, with the intermediate voltage and the second writing voltage being chosen so that a voltage drop across said ferroelectric transistors coupled to said word lines other than the at least one selected word line is lower in absolute value than the coercive voltage in absolute value, and
f) supply the second writing voltage to each one of the at least one selected word line, with the second writing voltage and the reference voltage being chosen so that a voltage drop across said ferroelectric transistors coupled to the both said at least one selected word and bit lines is higher in absolute value than the coercive voltage in absolute value, to set a second polarization state different than the first polarization state in said ferroelectric transistors coupled to both said at least one selected word and bit lines.

66. The ferroelectric memory according to claim 65, wherein said first and second plurality of generators are configured to operate simultaneously.

67. A ferroelectric memory comprising:
a plurality of word lines;
a plurality of bit lines;
a plurality of memory cells coupled between a respective word and bit line, with each memory cell comprising a ferroelectric transistor comprising a conduction terminal coupled to a bit line among said plurality of bit lines, and a control terminal coupled to a word line among said plurality of word lines, with each ferroelectric transistor having a coercive voltage so that when a voltage higher than the coercive voltage is applied between said conduction terminal and said control terminal, a polarization state of said ferroelectric transistor is changed;
a first plurality of generators electrically coupled to said control terminals of said ferroelectric transistors through a respective word line;
a second plurality of generators electrically coupled to said conduction terminals of said ferroelectric transistors through a respective bit line; and
a control logic configured to select at least one memory cell to be programmed by selecting at least one word line among said plurality of word lines and at least one bit line among said plurality of bit lines, with said memory cells to be programmed being coupled to both the at least one selected word and bit lines,
said first and second plurality of generators being operable to
a) supply a first writing voltage to each word line of said plurality of word lines,
b) supply a reference voltage, different from the first writing voltage, to each bit line of said plurality of bit lines, with the reference voltage and the first writing voltage being chosen so that a first polarization state is set in said ferroelectric transistor of each memory cell,
c) supply a second writing voltage to said at least one selected word line,
d) supply the second writing voltage to each bit line other than the at least one selected bit line,
e) supply an intermediate voltage to each word line other than the at least one selected word line, with the intermediate voltage and the second writing voltage being chosen so that a voltage drop across said ferroelectric transistors coupled to said word lines other than the at least one selected word line is lower in absolute value than the coercive voltage in absolute value, and
f) supply the reference voltage to selected bit lines, with the reference voltage and the second writing voltage being chosen so the a voltage drop across said ferroelectric transistors coupled to the both the at least one selected word and bit lines is higher in absolute value than the coercive voltage in absolute value, and in such a way to set a second polarization state different than the first polarization state in said ferroelectric transistors coupled to both said at least one selected word and bit lines.

68. The ferroelectric memory according to claim 67, wherein said first and second plurality of generators are configured to operate simultaneously.
